(19) United States
(12) Patent Application Publication
(10) Pub. No.: US 2007/0252178 A1
(43) Pub. Date: Nov. 1, 2007

(54) SEMICONDUCTOR DEVICE

(76) Inventor: Hidekatsu ONOSE, Hitachi (JP)

Correspondence Address: MILES & STOCKBRIDGE PC, 1751 PINNACLE DRIVE, SUITE 500, MCLEAN, VA, 22102-3833, US

(21) Appl. No.: 11/740,728

(22) Filed: Apr. 26, 2007

(30) Foreign Application Priority Data
Apr. 26, 2006 (JP) 2006-121760

(51) Int. Cl. H01L 31/112

(52) U.S. Cl. 257/270

(57) ABSTRACT

The present invention can maintain a blocking state, even at a low gate bias voltage, in a diode-containing type of junction FET, and achieves a large saturation current.

The junction FET includes: an n⁺ SiC substrate 10 as a drain layer; an n⁻ SiC layer 11 contiguous to the drain layer as a drift layer; an n⁺ SiC layer 12 formed on the drift layer as a source layer; trench grooves formed ranging from the source layer to a required depth of the drift layer and part of the drift layer as a channel region; and p-type polycrystalline Si formed in the trench grooves as gate regions. The gate region at one side of the channel is electrically shorted to a source electrode to form a p⁻ emitter of a diode.

### CLAIM OF PRIORITY

The present application claims priority from Japanese application JP 2006-121760 filed on Apr. 26, 2006, the content of which is hereby incorporated by reference into this application.

### BACKGROUND OF THE INVENTION

1. Field of the Invention

The present invention relates generally to semiconductor devices, and more particularly to a semiconductor device suitable for junction FETs (JFETs) or static induction transistors (SITs).

2. Related Art

In an inverter circuit constituted by JFETs or SITs, since a motor or the like is used as a load, a mode exists that causes inductance to generate a flow of a current in an inverse direction when the JFETs are off. In the inverter, therefore, a fly-wheeling diode for the current needs to be connected in antiparallel to each JFET, so the connection of the diodes correspondingly increases costs. There has also been the problem that dimensional reduction to a package size is limited.

Silicon carbide (SiC) having about 10 times the dielectric breakdown field strength of silicon (Si) is a material that makes it possible to form thinly and at high concentration the drift layer required for maintenance of its voltage-withstanding capabilities. For this reason, JFETs, one kind of power semiconductor element based on SiC, are anticipated as a device capable of reducing electrical loss, compared with Si, and as a device strong against breakdown. FIG. 10 shows a cross-sectional structure of a conventional JFET based on SiC. A diode for fly-wheeling is built into the conventional JFET as an improvement measure against the foregoing problems. In FIG. 10, reference number 10 is an n⁺ substrate that is a drain layer, 11 an n⁻ drift layer, 12 an n⁺ source region, 15 a p⁺ gate region, 21 a drain electrode, 22 a source electrode, and 23 a gate electrode. A high-concentration p⁺ region 16 is provided as a p⁺ emitter region in a central part of the n⁺ source region 12 and then electrically shorted thereto, whereby the JFET is formed with the built-in diode. Such a structure is disclosed in Japanese Laid-Open Patent Application Publication No. 2002-252552, for example.

### SUMMARY OF THE INVENTION

FIGS. 11A and 11B are diagrams showing a spread of a depletion layer in the case that a gate voltage and a source voltage are of the same potential (gate bias voltage of 0 V). FIG. 11A shows an “off” state, and FIG. 11B shows an “on” state. The depletion layer DP spreads to a channel CH as well as to an n⁻ drift layer 11. In this structure, since the width of the channel in SiC increases with the depth of the channel, the depletion region from a p⁺ emitter region 16 and the depletion region from a p⁺ gate 15 do not come into contact with each other in the state of gate bias voltage 0 V. To realize the “on” state in FIG. 11B and maintain a blocking state, therefore, the depletion region from the p⁺ gate region 15 needs to be spread by applying a negative bias voltage to a gate electrode 23. Although it is possible to bring both depletion layers into mutual contact at gate bias voltage 0 V by narrowing the channel width of the surface, this method requires narrowing the channel width significantly. The depletion layer from the p⁺ emitter region 16 is contiguous to a source electrode 22, so this depletion layer does not change with the gate voltage. If the depletion layer from the p⁺ emitter 16 is narrowed by applying a positive bias voltage to the gate, therefore, “on” resistance will increase and saturation drain current will significantly decrease. Since the channel width of the surface must be increased to ensure a sufficient saturation current, a greater negative gate bias must be applied to maintain the blocking state.

Accordingly, an object of the present invention is to provide a diode-containing type of semiconductor device capable of maintaining a blocking status and achieving a large saturation current, even at a low gate bias voltage.

Semiconductor device configurations disclosed in this Specification provide means of solving the foregoing problems, and an example of typical such means is outlined below. That is to say, a semiconductor device according to the present invention includes: a first electroconductive type of high-concentration SiC drain layer; a first electroconductive type of low-concentration SiC drift layer contiguous to the drain layer; a first electroconductive type of high-concentration SiC source layer formed on the drift layer; a channel region formed in part of the drift layer by using trench grooves formed beforehand so as to range from the source layer to a required depth of the drift layer; and gate regions of a second electroconductive type, each formed along a sidewall and bottom part of each of the trench grooves formed at both sides of the channel region, wherein the gate region at one side of the channel region is electrically shorted to the source layer.

In short, one of major features of the present invention is that a p-type region at one side of a channel in a trench junction FET is electrically shorted to a source electrode to form a p⁺ emitter of a diode for fly-wheeling.

FIGS. 2A and 2B are diagrams showing a spread of a depletion region DP in the JFET of the present invention. FIG. 2A shows an “off” state, and FIG. 2B shows an “on” state. Since the JFET employs trenched construction, a depletion region from a p⁺ emitter 16 and a depletion layer from a p⁺ type gate region 15 each come to overlap on the other efficiently. Accordingly, the “off” state shown in FIG. 2A can be realized at a low gate bias voltage, even for increased channel width. In addition, the fact that the channel width can be increased means that a larger saturation drain current can be created and thus that gate bias voltage reduction in the “off” state and improvement of a drain current in the “on” state can be simultaneously achieved in the junction FET having a built-in diode for fly-wheeling (hereinafter, this FET is referred to simply as the diode-containing junction FET).

Furthermore, for a normal junction FET, a p-type region that is a dead space in a current path, and a section under the p-type region are formed as a diode region, so the element that performs a fly-wheeling diode function and a transistor function can be realized with a chip area smaller than that obtained by summing up a normal junction FET area and a diode area.

### BRIEF DESCRIPTION OF THE DRAWINGS

FIG. 1 is a schematic cross-sectional view of a JFET that shows a first embodiment of a semiconductor device according to the present invention;

FIGS. 2A and 2B are explanatory diagrams showing a spread of a depletion layer in the JFET of FIG. 1, with FIG. 2A showing an “off” state and FIG. 2B showing an “on” state;

FIG. 3A is a cross-sectional view schematically showing the first manufacturing process for the JFET of FIG. 1;

FIG. 3B is a cross-sectional view schematically showing a manufacturing process which follows that of FIG. 3A;

FIG. 3C is a cross-sectional view schematically showing a manufacturing process which follows that of FIG. 3B;

FIG. 3D is a cross-sectional view schematically showing a manufacturing process which follows that of FIG. 3C;

FIG. 3E is a cross-sectional view schematically showing a manufacturing process which follows that of FIG. 3D;

FIG. 3F is a cross-sectional view schematically showing a manufacturing process which follows that of FIG. 3E;

FIG. 4 is a schematic cross-sectional view of a JFET, showing a second embodiment of a semiconductor device according to the present invention;

FIG. 5 is a schematic cross-sectional structural view of a JFET, showing a third embodiment of a semiconductor device according to the present invention;

FIG. 6 is a layout diagram showing a fourth embodiment of a semiconductor device according to the present invention;

FIG. 7 is a layout diagram showing a fifth embodiment of a semiconductor device according to the present invention;

FIG. 8 is an explanatory diagram of a three-phase inverter with JFETs in a sixth embodiment of the present invention, showing an electric-current path formed when JFETs 81, 86 are on and other JFETs are off;

FIG. 9 is an explanatory diagram of the three-phase inverter with the JFETs in the sixth embodiment of the present invention, showing another electric-current path formed when the JFETs 81, 86 are simultaneously turned off;

FIG. 10 is a schematic cross-sectional view of an example of a conventional JFET based on SiC; and

FIGS. 11A and 11B are diagrams showing a spread of a depletion layer in the JFET of FIG. 10, with FIG. 11A showing an “off” state and FIG. 11B showing an “on” state.

### DESCRIPTION OF NUMERALS

10 . . . n⁺ SiC substrate, 11 . . . n⁻ drift layer, 12 . . . n⁺ source layer, 15 . . . p⁺ gate region, 16 . . . p⁺ emitter region, 17, 18 . . . p-type SiC, 21 . . . Drain electrode, 22, 222 . . . Source electrode, 41 . . . Ion implantation mask material, 42 . . . Nitrogen ion, 70 . . . Capacitor, 71 . . . Inductive load, 81-86 . . . Diode-containing junction FETs, 87 . . . 2-in-1 module that uses diode-containing JFETs, 88 . . . 6-in-1 module that uses diode-containing JFETs, 151, 153, 161, 163 . . . High-concentration p-type Si, 152, 162 . . . Low-concentration p-type Si, 201, 202 . . . Oxide films, 211 . . . Silicide drain electrode, 221 . . . Silicide source electrode.

### BEST MODE OF CARRYING OUT THE INVENTION

Hereunder, embodiments of a semiconductor device according to the present invention will be described in detail with reference to the accompanying drawings.

### First Embodiment

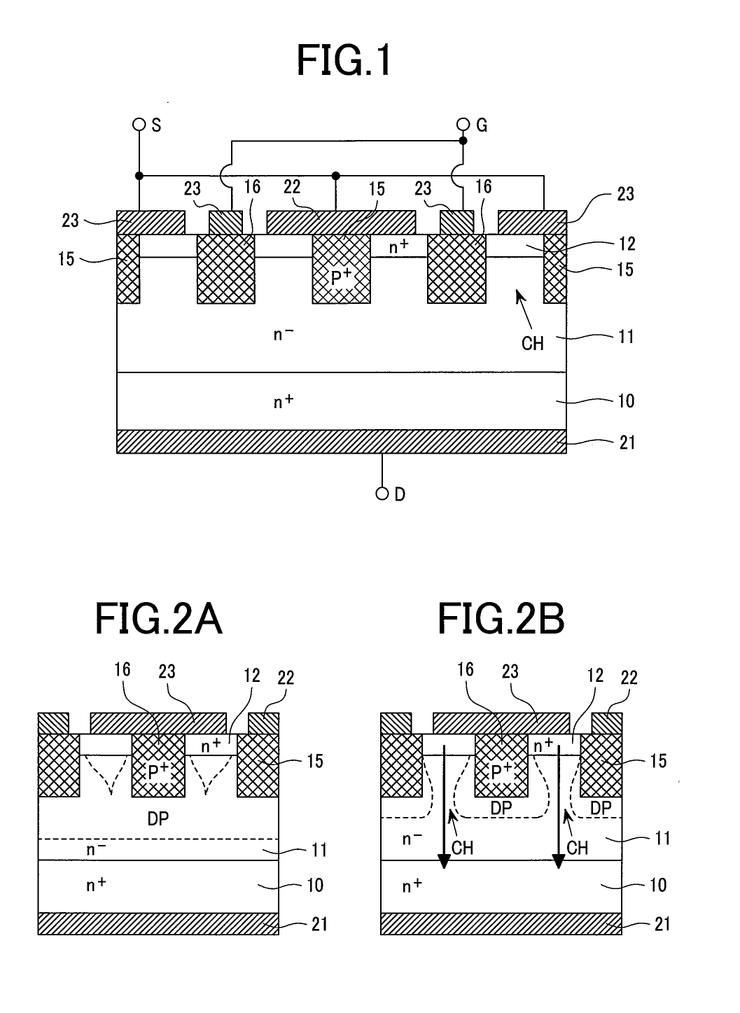

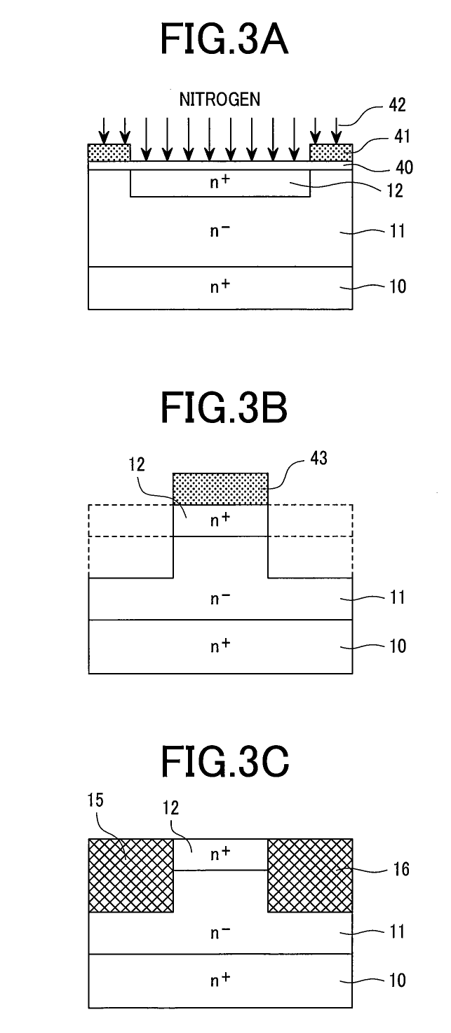

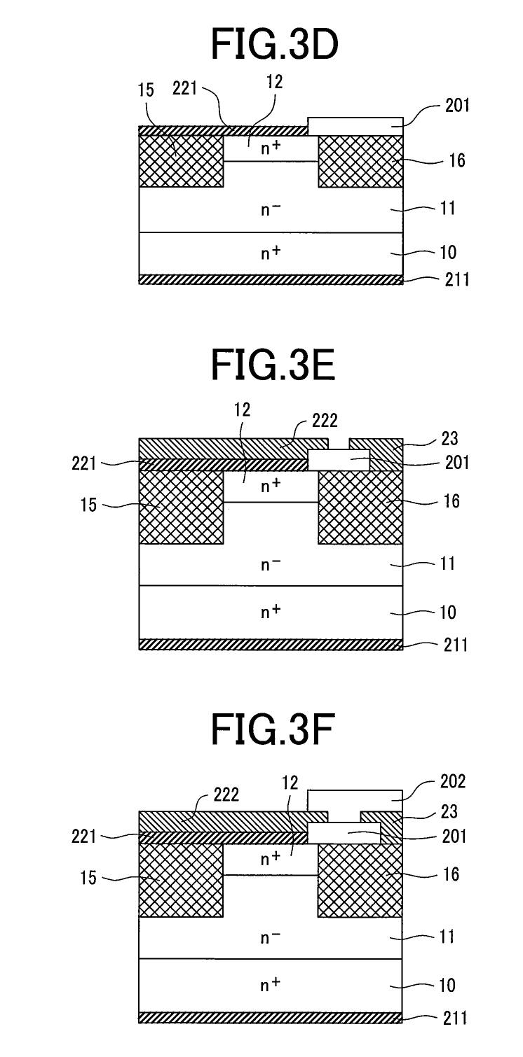

FIG. 1 is a cross-sectional view of a JFET, showing a first embodiment of a semiconductor device according to the present invention. In the first embodiment, construction that includes trench grooves filled with p-type polycrystalline silicon (hereinafter, referred to p-type poly-Si) is employed for a p⁺ gate region 15 and a p⁺ emitter region 16. FIGS. 3A to 3F are cross-sectional structural view schematically showing the process steps of forming the JFET of the first embodiment. These process steps are described in order below.

As shown in FIG. 3A, on an n⁺ SiC substrate 10 is first formed an n⁻ SiC drift layer 11 (2×10¹⁶ cm⁻² in concentration and 6.5 μm in thickness), on which is then formed an oxide film 40, and on which is further formed an ion implantation mask material 41. Next, the ion implantation mask material 41 on the oxide film 40 is patterned and nitrogen ions 42 are implanted to form an n⁺ SiC source 12 (1×10²⁰ cm⁻² in peak concentration and 0.25 μm in thickness).

As shown in FIG. 3B, after removal of the oxide film 40 and the mask material 41, heat treatment is provided at 1,700° C. to activate the implanted nitrogen ions. After the heat treatment, an etching mask material 43 made of an oxide film, for example, is formed on the n⁺ SiC source 12, then patterned, and dry-etched to form trenches (1.4 μm in trench width, 0.6 μm in trench spacing, and 1.5 μm in trench depth).

Next as shown in FIG. 3C, the trenches are filled with p-type poly-Si 15, 16, thereby to form planar regions having a concentration of 1×10¹⁸ cm⁻³. Epitaxial growth of p-type SiC is usually used to fill in these trenches. In the present embodiment, however, p-type poly-Si is used to form the trenches in terms of facility of the process steps and ease in formation of gate electrode contacts.

Next as shown in FIG. 3D, after formation of an oxide film 201 on the surface, a nickel/titanium (Ni/Ti) film stack 211 to function as a drain electrode is formed on the surface of the n⁺ SiC substrate which is a drain. Additionally, the oxide films on the surface of the n⁺ source 12 and on the surface of the poly-Si 15 which is the p⁺ emitter region are removed, then an Ni/Ti film stack 221 to function as a source electrode is formed, and 1,000° C. heat treatment is conducted to change the Ni/Ti film stacks 211, 221 into silicide.

Next as shown in FIG. 3E, a gate contact window is formed at the oxide film 201 of the poly-Si 16 which is a p⁺ gate region. After that, an aluminum (Al) electrode is formed, the electrode of which is then separated into a source Al electrode 222 and a gate Al electrode by etching.

The JFET construction of the present invention, shown in FIG. 1, is now completed (see FIG. 3F). For simplicity, the silicide 221 formed from the Ni/Ti film stack, and the gate Al electrode 222 are collectively shown as a source electrode 22 in FIG. 1.

A gate electrode 23 is formed on the p-type poly-Si 16 at one side of a channel. Although the p-type poly-Si 15 at the other side of the channel originally ought to become a p⁺ gate region in the JFET, the p-type poly-Si 15 becomes a p⁺ emitter since the poly-Si 15 is electrically shorted to the source electrode (S) 22. After this, the p⁺ emitter is combined with the n⁻ layer 11, the n⁺ SiC substrate layer 10, and the drain electrode (D) 21, thereby to form a pn diode. Applying a negative bias voltage to the gate electrode (G) spreads the depletion region DP in the channel region (CH), thus realizing such an “off” state as shown in FIG. 2A.

When a positive bias voltage is applied to the gate, the depletion region at the p-type poly-Si 16 is narrowed to open the channel, and thus as indicated by a thick arrow in FIG. 2B, electrons flow from the source electrode S to the drain electrode D (current flows from the drain electrode to the source electrode), resulting in the JFET being turned on. In the present embodiment, a source-drain withstand voltage of 450 V can be achieved by applying a gate voltage of −5 V, and a saturation drain current of 400 A/cm2 can be attained by applying a gate voltage of 2.5 V. For a trench spacing of 0.45 μm, a withstand voltage of 400 V can be obtained at a gate voltage of 0 V. Normally-off operation can also be implemented. A saturation drain current obtainable in that case is 200 A/cm2.

That is to say, even at a low gate bias voltage, a blocking state can be maintained and a large saturation current achieved.

### Second Embodiment

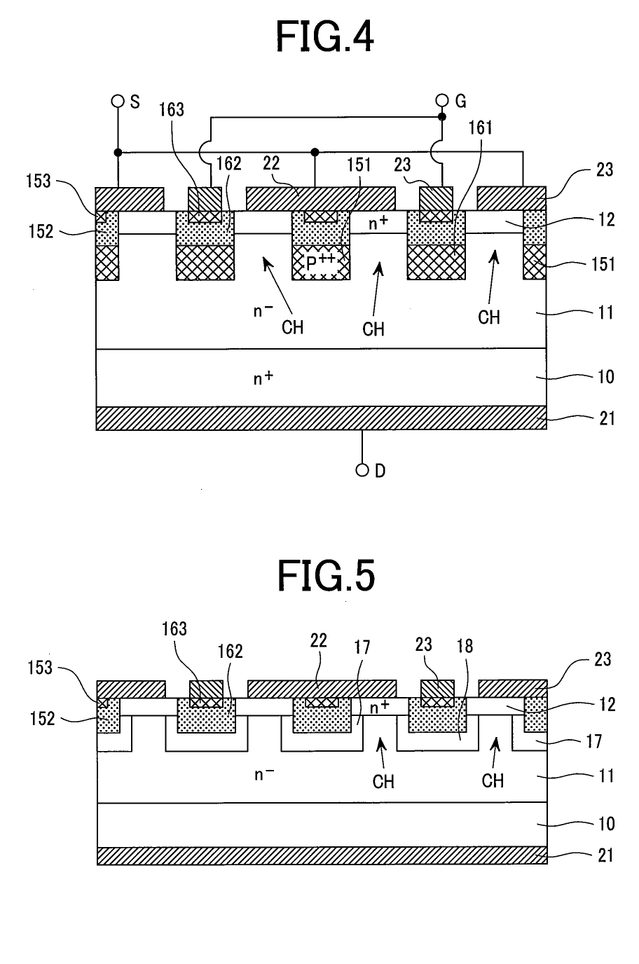

FIG. 4 is a cross-sectional structural view of a JFET, showing a second embodiment of a semiconductor device according to the present invention. The first embodiment uses the p-type poly-Si of the same concentration to fill in the entire trench. To prevent malfunctioning during switching, it is desirable that even in a normally-off state, a negative voltage be capable of being applied to the gate, and reliability of the source-gate withstand voltage needs to be guaranteed. In the present (second) embodiment, therefore, sidewalls of a channel that come into contact with an n⁺ source 12 of a poly-Si filler are formed as low-concentration sections 152, 162 (concentration: 2×10¹⁷ cm⁻³), and bottom sections of the channel, as high-concentration sections 151, 161 (concentration: 5×10¹⁹ cm⁻³).

This makes it possible to ensure a desired source-gate withstand voltage and to improve “off” performance. However, since direct contact of an electrode to the low-concentration poly-Si 162 increases contact resistance, the present embodiment is constructed so that the low-concentration poly-Si 162 partly includes a high-concentration contact region 153, 163 (concentration: 2×10¹⁹ cm⁻³). Accordingly, the source-gate withstand voltage rises from 10 V to 50 V, so a source-drain withstand voltage of 670 V can be realized by applying a gate voltage of −15 V.

### Third Embodiment

FIG. 5 is a cross-sectional structural view of a JFET, showing a third embodiment of a semiconductor device according to the present invention. To realize a high withstand voltage with a pn junction formed up of p-type poly-Si 163, 153 and n-type SiC, the poly-Si requires a concentration from a level slightly below 10²⁰ cm⁻³ to an order of 10²⁰ cm⁻³. In this context, the present embodiment is constructed to achieve a high withstand voltage at a poly-Si concentration of an order of 10¹⁸ cm⁻³, and has a p-type SiC layer 17, 18 at bottom sections of trenches and at sidewalls of each trench. The p-type SiC layers 17, 18 are 1×10¹⁸ cm⁻³ in concentration and 0.2 μm in thickness. The trenches in this case are 1.0 μm spaced and have a width of 1.0 μm and a depth of 1.3 μm. This trench structure renders a high withstand voltage of 750 V achievable without generating a high electric field in the poly-Si 163, since a depletion layer from a drain side of an n⁻ drift layer 11 stays inside the p-type SiC layer 18.

### Fourth Embodiment

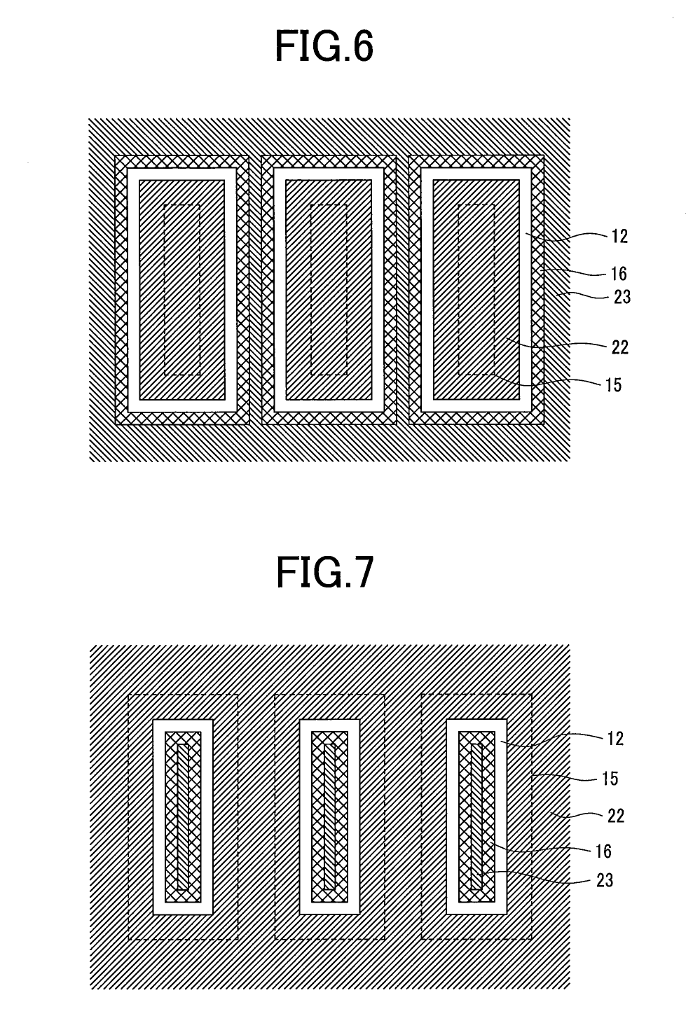

FIG. 6 is a layout diagram illustrating a fourth embodiment of a semiconductor device according to the present invention. Although the present embodiment is described below taking the JFET of the first embodiment as an example, the description also applies to a JFET in any other embodiment disclosed herein. For a normal trench JFET, the p-type regions at both sides of the channel are connected since all these regions are gate regions. In contrast to this, the trench JFET of the present invention has a construction with one p⁺ region formed as a p⁺ emitter region electrically shorted to a source electrode, so the p⁺ emitter region needs to be separated from another p⁺ region that is a p⁺ gate region. For this reason, the p⁺ emitter region 15 is surrounded by an n⁺ source 12 in the present embodiment. The p⁺ gate region 16 is disposed in such a form as to be connected to the outside of the n⁺ source 12 which surrounds the p⁺ emitter region 15. This layout separates the p⁺ emitter region 15 from the p⁺ gate region 16, prevents both regions from affecting each other, and renders a diode-containing JFET.

### Fifth Embodiment

FIG. 7 is a layout diagram illustrating a fifth embodiment of a semiconductor device according to the present invention. The present embodiment, contrary to the fourth embodiment, is constructed to include a p⁺ gate region 16 surrounded by an n⁺ source 12, and have a p⁺ emitter region 15 disposed in such a form as to be connected to the outside of the n⁺ source 12 which surrounds the p⁺ gate region 16. This layout, as with the layout in the fourth embodiment, separates the p⁺ emitter region 15 from the p⁺ gate region 16, prevents both regions from affecting each other, and renders a diode-containing JFET.

### Sixth Embodiment

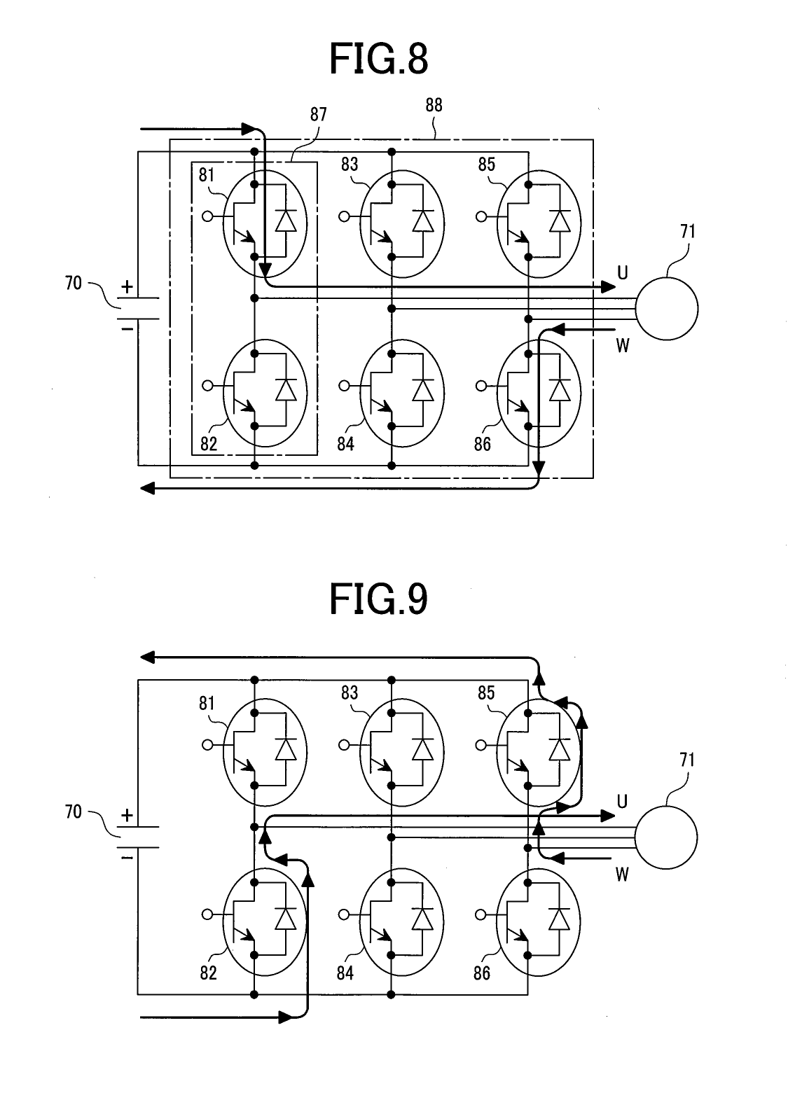

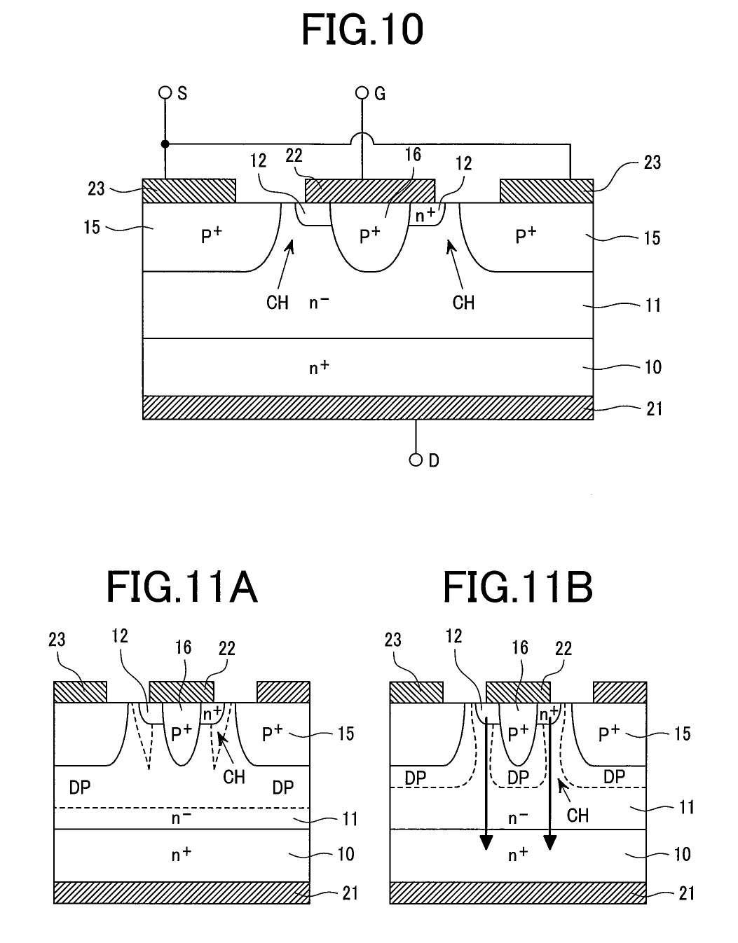

FIGS. 8, 9 are circuit diagrams illustrating a sixth embodiment of a semiconductor device according to the present invention. In the figures, reference number 70 denotes a capacitor that is a direct-current power supply, 71 denotes a load such as a motor, and 81 to 86 each denote a diode-containing JFET of the present invention. When the diode-containing JFET of the present invention is to be used in an inverter circuit or the like, the packaged element itself may be used alone as a discrete component to compose the circuit. Usually, however, two diode-containing JFETs are packaged to form a two-in-one module 87 equivalent to either phase U, V, or W, or alternatively, six diode-containing JFETs are packaged to form a six-in-one module 88 that realizes phases U, V, and W.

Since the present invention features chip size reduction, the present embodiment is applied to the six-in-one module constructed by packaging the six kinds of diode-containing JFETs of the invention. This application makes it possible to dimensionally reduce the module to ⅔ of the module compared with conventional six-in-one packaging.

Next, part of circuit operation is described below. FIG. 8 shows a state in which a current is flowing from phase U of an inductive load 71 to phase W. In this state, JFETs 81 and 86 are on and all other JFETs are off. The current flows from a plus side of a power supply 70 through the JFET 81 to phase U of the inductive load 71, and after flowing through phase W, returns to a minus side of the power supply 70 through the JFET 86. FIG. 9 shows a state in which the JFETs 81 and 86 are simultaneously turned off. Even when all JFETs are turned off, inductance of the load 71 acts to maintain a continued flow of the current without causing a momentary current-off state. Accordingly, the diode of the JFET 82 paired with that of the JFET 81, and the diode of the JFET 85 paired with that of the JFET 86 are turned on.

The flow of the load current in the entire circuit completely differs from that of the “on” state. That is to say, the current flows from the minus side of the power supply 70 through the diode of the JFET 82 to phase U of the inductive load 71, and after flowing through phase W, returns to the plus side of the power supply 70 through the diode of the JFET 85. When viewed from the power supply, this flow of the current is inverse, so the flow is braked and diminishes.

In this case, since a supply voltage is applied to the diode-containing JFETs 81 and 86, no external voltage is applied to the diode-containing JFETs 82 and 85. Even when the JFET section is off, since no depletion region spreads to the diode section, the diode current can flow. Even for a structure that contains fly-wheeling diodes, therefore, problems associated with operation do not occur and highly efficient inverter operation in a compact module compared with the conventional module can be achieved.

In addition, each fly-wheeling diode and each JFETs can be formed simultaneously and this, in turn, makes it possible to reduce costs and to implement essentially the same function at a smaller size than when the diode and the JFET are formed in separate chips. Accordingly, the module constructed of JFETs and diodes can be miniaturized and the inverter system can also be miniaturized.

What is claimed is:

1. A semiconductor device comprising:
a first electroconductive high-concentration SiC drain layer;
a first electroconductive low-concentration SiC drift layer contiguous to the drain layer;
a first electroconductive high-concentration SiC source layer formed on the drift layer;
a channel region formed in part of the drift layer by using trench grooves formed beforehand so as to range from the source layer to a required depth of the drift layer; and
gate regions of a second electroconductive type, each formed on a sidewall and bottom part of each of the trench grooves formed at both sides of the channel region, wherein
the gate region at one side of the channel region is electrically shorted to the source layer.

2. The semiconductor device according to claim 1, wherein:
the second electroconductive type of gate region is a second electroconductive type of Si gate region formed in each of the trench grooves.

3. The semiconductor device according to claim 2, wherein:
a substantially entire Si gate region along a sidewall part of the channel region is of a high concentration;
an Si gate region along a sidewall part and neighboring part of the source region is of a low concentration; and
a high-concentration Si region is formed on the surface of the low-concentration Si gate region.

4. The semiconductor device according to claim 1, wherein:
the gate region electrically shorted to the source region is disposed so as to be surrounded by the source region.

5. The semiconductor device according to claim 2, wherein:
the gate region electrically shorted to the source region is disposed so as to be surrounded by the source region.

6. The semiconductor device according to claim 3, wherein:
the gate region electrically shorted to the source region is disposed so as to be surrounded by the source region.

7. The semiconductor device according to claim 1, wherein:
the other gate region that is not electrically shorted to the source region is disposed so as to be surrounded by the source region.

8. The semiconductor device according to claim 2, wherein:
the other gate region that is not electrically shorted to the source region is disposed so as to be surrounded by the source region.

9. The semiconductor device according to claim 3, wherein:
the other gate region that is not electrically shorted to the source region is disposed so as to be surrounded by the source region.

10. An electric circuit comprising:
a first electroconductive high-concentration SiC drain layer;
a first electroconductive low-concentration SiC drift layer contiguous to the drain layer;
a first electroconductive high-concentration SiC source layer formed on the drift layer;
a channel region formed in part of the drift layer by using trench grooves formed beforehand so as to range from the source layer to a required depth of the drift layer;
gate regions of a second electroconductive type, each formed on a sidewall and bottom part of each of the trench grooves formed at both sides of the channel region; and
a junction FET having a structure in which the gate region at one side of the channel region is electrically shorted to the source layer.

11. An electric circuit comprising the junction FET according to claim 10, wherein:
the junction FET has a structure in which the second electroconductive type of gate region is a second electroconductive type of Si gate region formed in each of the trench grooves.

12. An electric circuit comprising the junction FET according to claim 10, wherein:
the junction FET has a structure in which:
a substantially entire Si gate region on a sidewall part of the channel region is of a high concentration;
an Si gate region on a sidewall part and neighboring part of the source region is of a low concentration; and
a high-concentration Si region is formed on the surface of the low-concentration Si gate region.

13. An electric circuit comprising the junction FET according to claim 10, wherein:
the junction FET has a structure in which the gate region electrically shorted to the source region is disposed so as to be surrounded by the source region.

14. An electric circuit comprising the junction FET according to claim 10, wherein:
the junction FET has a structure in which the other gate region not electrically shorted to the source region is disposed so as to be surrounded by the source region.

15. The electric circuit according to claim 10 constructed as a three-phase inverter circuit.

16. The electric circuit according to claim 11 constructed as a three-phase inverter circuit.

17. The electric circuit according to claim 12 constructed as a three-phase inverter circuit.

18. The electric circuit according to claim 13 constructed as a three-phase inverter circuit.

19. The electric circuit according to claim 14 constructed as a three-phase inverter circuit.
